(19) United States
(12) Patent Application Publication
(10) Pub. No.: US 2026/0293126 A1
(43) Pub. Date: Sep. 24, 2026

(54) 3D-DRAM WITH ONE-SIDE STAIRCASE LAYOUT

(71) Applicant: Micron Technology, Inc., Boise, ID (US)

(72) Inventors: HIROKI FUJISAWA, Kanagawa (JP); DAIKI SAITO, Kanagawa (JP)

(73) Assignee: Micron Technology, Inc., Boise, ID (US)

(21) Appl. No.: 19/556,066

(22) Filed: Mar. 4, 2026

Related U.S. Application Data
(60) Provisional application No. 63/776,561, filed on Mar. 24, 2025.

(51) Int. Cl. H10B 12/00; G11C 11/408; G11C 11/4091

(52) U.S. Cl. CPC H10B 12/50; G11C 11/4085; G11C 11/4091; H10B 12/30

(57) ABSTRACT

A 3D memory device includes multiple memory patches each of which includes a 3D array of memory cells arranged at the intersection of word lines running in a first direction, local digit lines (LDLs) running in a second direction, and global digit lines (GDLs) running in a third direction. A memory section includes two memory patches with a staircase region in between. The word lines run continuously through the two patches and through the in-between staircase region. Sub-word line drivers (SWDs) are positioned above the staircase region and coupled to respective ones of the word lines by conductive elements running in the second direction. In this way the SWDs may be located in a middle of the memory section.

### CROSS REFERENCE TO RELATED APPLICATION(S)

This application claims the benefit under 35 U.S.C. § 119 of the earlier filing date of U.S. Provisional Application Serial No. 63/776,561 filed Mar. 24, 2025. The aforementioned application is incorporated herein by reference, in its entirety, for any purpose.

### BACKGROUND OF THE INVENTION

Memory devices, such as DRAM devices have generally decreased in size and increased in capacity over time. Many of these gains have been accomplished by miniaturizing circuits such as the sense amplifier, sub-word line driver, and so for forth across different generations of memory devices. However, it is difficult to decrease the size of components below certain size thresholds, which makes it difficult to continue to improve memory device capacity and size in this manner.

It may be possible to increase memory device size and capacity by arranging memory cells in a three dimensional grid instead of a two-dimensional array. For example, multiple memory chips may be stacked on top of each other. However, this increases the thickness of the overall memory device to an extent that may be difficult to accommodate and the number of stacked chips is limited by concerns such as the length of signal lines through the stack, alignment of timing signals, and so forth. Other technologies may be used to generate 3D arrays of memory cells, such as the 3D arrays found in flash memory, but these may have limitations in the speed at which the memory device operates and are generally much slower than the speeds required of a DRAM device. There may be a need for 3D memory devices which operate at high speeds.

### BRIEF DESCRIPTION OF DRAWINGS

FIG. 1 is a block diagram of a 3D memory device according to some embodiments of the present disclosure.

FIG. 2A is a perspective drawing of a single die memory die with an inset showing a ‘top down’ view of two example memory sections according to some embodiments of the present disclosure.

FIG. 2B is a is a perspective drawing of a stacked die memory device with an inset showing a ‘top down’ view of two example memory sections according to some embodiments of the present disclosure.

FIG. 3 is a perspective schematic diagram of a portion of a 3D memory array according to some embodiments of the present disclosure.

FIG. 4 is a perspective view of a portion of a 3D memory device according to some embodiments of the present disclosure.

FIG. 5 is a cross sectional view of a 3D memory device according to some embodiments of the present disclosure.

FIG. 6 is a cross sectional view of a 3D memory device according to some embodiments of the present disclosure.

FIG. 7 is a cross sectional view of a 3D memory device according to some embodiments of the present disclosure.

FIG. 8 is a flow chart of a method of activating word lines in a 3D memory device according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells which store information. For example each memory cell may store a single bit of information as a charge on a capacitive element. In a conventional 2D memory device, the memory cells are logically organized at the intersection of rows and columns. Conductive elements known as word lines couple memory cells along a row, and conductive elements known as digit lines or bit lines couple memory cells along a column. Accordingly, a row address may be used to specify a word line and a column address may be used to specify one or more of the digit lines.

The memory array may be formed of repeating units, referred to as ‘sections’ or ‘tiles’. These sections include one or more patches of the memory array and various circuits which support the operation of that patch. For example, a section may include the patch, sense amplifiers (SA) coupled to the digit lines of that patch, and sub-word line drivers (SWD) coupled to the word lines of the patch. For example, in a conventional 2D memory device, the memory array patch may be generally rectangular with SAs positioned along a ‘top’ and ‘bottom’ edge of the patch and SWDs positioned along a ‘left’ and ‘right’ edge. The top row of sense amplifiers are coupled to either even or odd digit lines (in this and in an adjacent patch), the bottom row of sense amplifiers are coupled to the other digit lines (in this and in an adjacent patch). The SWDs along the edges are similarly coupled to alternate word lines in the patch.

While this layout may be efficient for 2D memory devices, when a third dimension is added, it may become more complicated to generate sections which are compact and which repeat across the memory device. For example, the need for connections to run in a third axis may complicate the placement of components such as SAs and SWDs compared to 2D memory. In addition the expansion into a third dimension may increase the memory cell density enough that it is possible to relax the pitch or spacing between components, which may allow more flexible layouts to be used compared to the layouts which are possible with the stringent pitch requirements of 2D memory. For example, a 3D memory device may have generally greater spacing between components such as word lines, sense amplifiers, and sub-word line drivers compared to a 2D memory. There may be a need for new section layouts in 3D-DRAM devices.

The present disclosure is drawn to apparatuses, systems, and methods for 3D-DRAM with a one-side staircase. An example 3D-DRAM device includes memory cells arranged at the intersection of word lines and local digit lines with the local digit lines coupled together by global digit lines. The word lines, local digit lines, and global digit lines may generally extend in directions which are mutually orthogonal to each other. The present application uses the convention that the word lines generally extend along an ‘x’ direction, the local digit lines generally extend along a ‘z’ direction, and the global digit lines generally extend along a ‘y’ direction. The x, y, and z directions may be orthogonal to each other.

Each section of the 3D-DRAM includes one or more memory array patches, sense amplifier regions, and sub-word line driver regions. The SAs and SWDs may generally be positioned such that a bottom of the SA and SWD regions is above a top of the memory cell patches in the z direction. The section includes two memory array patches separated by a staircase region. Word lines extend along the x axis through one memory array patch, through the staircase region, and through the other memory array patch. The staircase region includes the portion of the word lines which passes therethrough, but no memory cells and thus no local digit lines or global digit lines. The SWDs are positioned above staircase region with respect to the z axis. Each SWD in the SWD region has vertical (in the z direction) connective element which couples the SWD to the associated word line. In this manner, the SWDs are positioned in a middle of the section, between the two memory array patches. This makes the overall section more compact, because it does not have SWDs positioned on the outside edges. It also allows the word line to be coupled to the respective driver in a region around the center of the word line.

In an example implementation, the memory array and the support circuits such as the SAs and SWDs may all be printed on a same circuit wafer. In another example implementation, the memory array and staircase region may be printed on a first chip. The support circuits such as the SAs and SWDs may be printed on a second chip. The second chip may be positioned above the first chip and the two chips may be connected, for example via wafer to wafer (W2W) bonding.

In some aspects, the present application relates to the spatial arrangement of various components. As used herein, when a circuit element is referred to as extending in or along a direction or axis, it refers to a component that is primarily extended in that dimension. However, such an element need not be a perfect line and may have portions which do not exclusively run in the given direction. For example, while a word line may primarily extend along the x axis, it may have portions which extend in the y and/or z directions. As used herein, when a component is referred to as being ‘above’ or ‘below’ another component, it means that at least a portion of the footprint of that component overlaps at least a portion of the footprint of the other component when projected on at least one plane but that they are offset in at least one axis. For example, the SWD region may be above the staircase region in the z direction. At least a portion of the xy footprint of the SWD region overlaps at least a portion of the xy footprint of the staircase region, however the SWD region occupies a different range of space long the z coordinate than the staircase region.

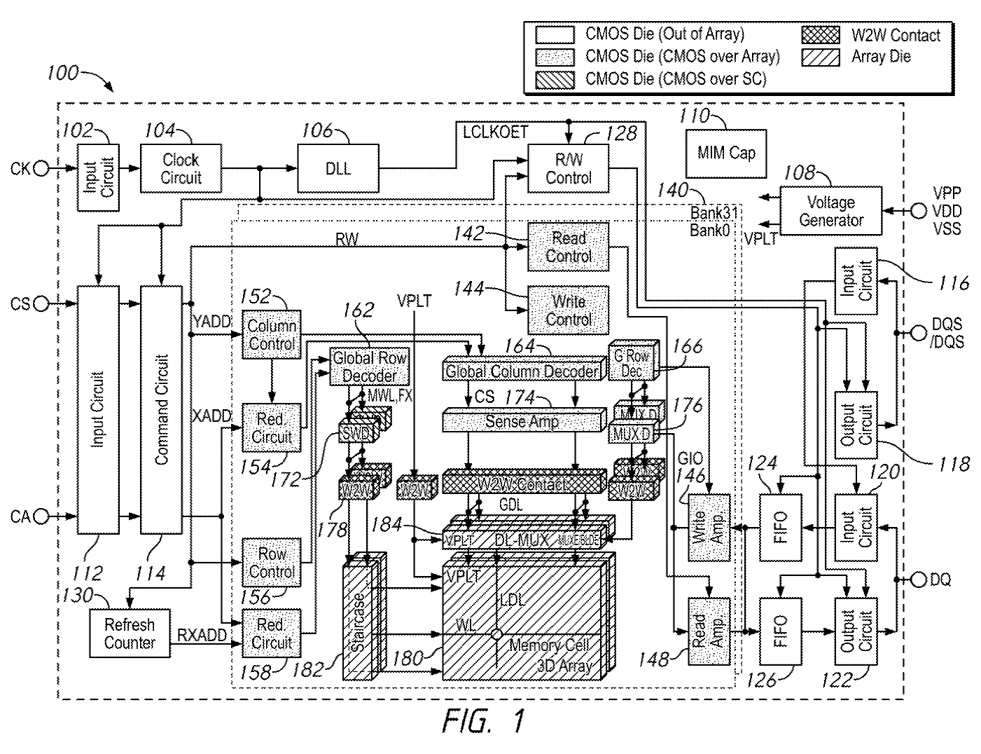

FIG. 1 is a block diagram of a 3D memory device according to some embodiments of the present disclosure. The view of the 3D memory device 100 in FIG. 1 is a block diagram representing the different components of the 3D memory device 100. It does not represent the spatial layout of the components of the device, except where otherwise noted.

The 3D memory device 100 may be coupled to a controller (not shown in FIG. 1) which provides various commands, data, and other signals to the 3D memory device 100 to operate the memory. In some embodiments, the 3D memory device 100 may be a stand-alone device. In some embodiments the 3D memory device 100 may be part of a module that packages together several similar memory devices.

The 3D memory device 100 includes a number of external terminals which receive various signals which are used by the device 100. The signals which are received, as well as the signals within the 3D memory device 100, are generally represented by voltages, which different levels of voltage representing different states of the signal. For example, many of the signals used by the 3D memory device 100 may be binary signals, where a first voltage level represents a logical high and a second voltage level represents a logical low. Example terminals include a clock terminal CK, a chip select terminal CS, a command/address terminal CA, data strobe terminals DQS and /DQS, data terminals DQ, and voltage terminals such as VPP, VDD, and VSS. Any of those example terminals may include one or more individual terminals.

The clock signal CK is received by the clock terminal and provided through an input circuit 102 to a clock circuit 104. The clock signal CK is used to control the timing of operations in the memory device 100. The clock circuit 104 generates one or more internal clock signals based on the external clock signal CK and distributes them to various other components of the memory device 100. The clock circuit 104 also provides the clock signal to a delay locked loop (DLL) circuit 106 which generates a delayed clock signal LCLKOET. The delayed clock circuit may be used to match a timing it takes the clock signal to propagate through the 3D memory device 100 and may be used to time read operations. The 3D memory device 100 also receives and provides data strobes DQS and /DQS through a respective input circuit 116 and output circuit 118. During write operations the 3D memory device receives a data strobe signal used to time operations of the input circuit 120 for the data DQ. During read operations the memory 100 provides the delayed clock signal LCLKOET to time the operations of a data output circuit 122 to the data terminal DQ. Buffer circuits 124 and 126, such as FIFO buffers, are used to serialize or deserialize data between the 3D memory device 100 and the DQ terminals.

The 3D memory device 100 receives voltages at voltage terminals. The voltages are provided to a voltage generator circuit 108 which generates one or more internal voltages based on the provided voltages. The provided voltages as well as the generated voltages are distributed to the various circuits of the 3D memory device 100. For example, the 3D memory device 100 may receive a ground voltage VSS and a system voltage VDD as well as a voltage VPP. The memory includes a metal-insulator-metal (MIM) capacitor 110 which may be used to help regulate voltages in the 3D memory device 100.

The memory receives commands and addresses along a command/address bus coupled to CA terminals. The 3D memory device 100 also receives a chip select signal CS, which is used to time signals along the CA terminals, as well as indicate which 3D memory device 100 is receiving commands and addresses in embodiments where multiple memory devices are packaged together. The CS and CA signals are passed through an input circuit 112 to a command/address circuit 114. Examples of addresses include bank address which specifies a bank of the 3D memory device 100, row address XADD which specifies a row of the device, and column address YADD which specifies a column of the device. Examples of commands include activation commands, pre-charge commands, access commands such as read R or write W, or refresh commands. Certain commands and addresses may generally be received together. For example the CA terminal may receive a row activation command ACT along with a row address XADD and bank address BADD. Access commands such as read R or write W may generally be received along with a column address YADD. A read/write control circuit 128 helps manage the RW commands.

The 3D memory device 100 is divided into one or more memory banks 180. In the embodiment of FIG. 1, there are 32 banks, labelled Bank0to Bank31. More or fewer banks may be used in other example embodiments. Each bank is associated with a bank logic region 140, which includes the memory array 180 of the bank as well as various circuits associated with that bank. These circuits may generally be repeated on a bank-by-bank basis. An example bank logic region 140 may include a column control circuit 152 and column redundancy circuit 154, a row control circuit 156 and row redundancy circuit 158, global row decoder circuits 162 and 166, global column decoder circuit 164, sub-word line drivers 172, sense amplifiers 174, multiplexer drivers 176, the array 180 and staircase region 182 (also referred to as a staircase), digit line multiplexers 184, write amplifiers 146 and read amplifiers 148.

The memory array 180 is a 3D array with memory cells coupled at the intersection of word lines WL and local digit lines LDL. The view of FIG. 1 shows an example slice of the array through an xz plane, showing an example WL and LDL. The LDLs are coupled together along a y axis by global digit lines GDL. The GDLs couple to the sense amplifiers 174. In some embodiments, multiplexers 184 are used to select which LDL is coupled to the respective GDL, and through that GDL to the sense amplifier. A global row decoder 166 is used to selectively activate multiplexer drivers 176, which activate respective multiplexers 184. In some embodiments, the multiplexers 184 and their respective drivers 176 may be eliminated.

The row control circuit 156 activates a word line of the memory array 180 based on the row address. The row control circuit 156 provides internal signals to global row decoder circuits 162 and 166. The global row decoder circuit 162 activates a sub-word line driver 172 associated with the word line specified by row address XADD. For example, the global row decoder circuit 162 may provide control signals such as a main word line signal MWL, an activation signal FX or combinations thereof to the sub-word line drivers 172. The control signals may select which sub word line driver 172 is activated. The sub-word line driver 172 is coupled to an associated word line WL through the staircase 182. The sub-word line driver 172 selected by the row address XADD activates the associated word line, causing the memory cells along that word line to couple to the intersecting local digit lines LDLs. The LDLs in turn are coupled along intersecting global digit lines GDLs to the sense amplifiers 174. In some embodiments, the global row decoder circuit 166 activates a multiplexer driver 176 which in turn selects multiplexers 184 to couple the LDLs which intersect the selected word line to the GDLs, and isolate other LDLs coupled to that GDL.

The column control circuit 152 selects global digit lines GDL to couple to global input/output lines GIO based on the column address YADD. During a write operation, the GIO lines are coupled to a write amplifier 146, which provides data received from the input circuit 120 through the GIO lines to the selected GDL lines and through those to the memory cells at the intersection of the selected WL and LDL. During a read operation, the data from the memory cells at the intersection of the selected WL and LDL are coupled through the selected GDL to the read amplifier 148, which provides the read data to the output circuit 122.

The memory bank logic region 140 also includes redundancy circuits 154 and 158. The redundancy circuits 154 and 158 are used as part of repair operations. If a row or column address has been repaired, the redundancy circuits 154 or 158 will direct access to a redundant word line or redundant column.

In an example write operation, data received along the DQ terminals is written to specified memory cells of the 3D memory device 100. The device 100 receives a row activation command along with a row address XADD. The global row decoder 162 selects SWDs 172 to activate the associated word line based on the row address XAD. The device 100 receives a write command along with a column address YADD. Data is received by the input circuit 120 and deserialized by a buffer circuit 124 which provides the data to write amplifiers 146. The global column decoder 164 couples selected global digit lines GDL to the GIO lines based on the column address YADD. The data from the write amplifier 146 is written along the GIO lines to the LDL lines and into the memory cells at the intersection with the active word line WL.

In an example read operation, data from the memory array 180 is provided out along the DQ terminals. The device 100 receives a row activation command along with a row address XADD. The global row decoder 162 selects SWDs 172 to activate the associated word line based on the row address XADD. Data is read out from the memory cells which intersect the active word line through the intersecting LDLs and along the GDLs. The device 100 receives a read command along with a column address YADD. Data is read out from selected ones of the GDLs along the GIO lines to a read amplifier 148. The read amplifier 148 provides the read data to a buffer 126 which serializes the data and provides the serialized data to the output circuit 122.

The 3D memory device 100 may also perform refresh operations. As part of a refresh operation, one or more word lines have the data in the intersecting memory cells refreshed. For example, the memory cells may store information as charge on a capacitive element, and that charge may decay over time. A refresh operation restores that charge to a nominal value. Responsive to a refresh command, a refresh control circuit 130 provides one or more refresh addresses RXADD which specify which word line or word lines should be refreshed.

FIG. 1 generally shows the 3D memory device 100 as a flattened 2D drawing. However certain components may be positioned over other components in an example implementation. For example, one or more circuits of the bank logic region 140 may be positioned ‘above’ (in the z direction) the memory arrays 180. For example, the sub-word line drivers 172 may be positioned above the staircase 182.

In some embodiments, the memory device 100 may be printed on a single chip. In some embodiments, the memory device 100 may be printed on two chips, which are then bonded together. For example, components such as the array 180, staircase 182 and digit line multiplexers 184 may be printed in an array die, while the other components are printed on a CMOS die. A set of wafer to wafer (W2W) contacts 178 couple the CMOS die to the array die. Shading is used in FIG. 1 to represent an example distribution of components between a CMOS die and an array die. The label CMOS over array indicates components which are in a portion of the CMOS die which is above a portion of the array die which has memory array patches. However the components labeled CMOS over array are not necessarily directly over the memory patches, and may, for example, be above interpatch regions, gaps between patches, etc., as described in more detail herein. The label CMOS over SC indicates components, such as the SWDs 172 which are over the staircase 182. The label out of array indicates that the components are in the CMOS die, but in a portion, such as a peripheral portion, which isn’t above the region of the array die including the array patches. While shading is shown to represent the arrangement of certain components between different dies, other arrangements may be used in other example embodiments. In some embodiments the 3D memory device 100 may be on a single chip and the shading of FIG. 1 may be ignored.

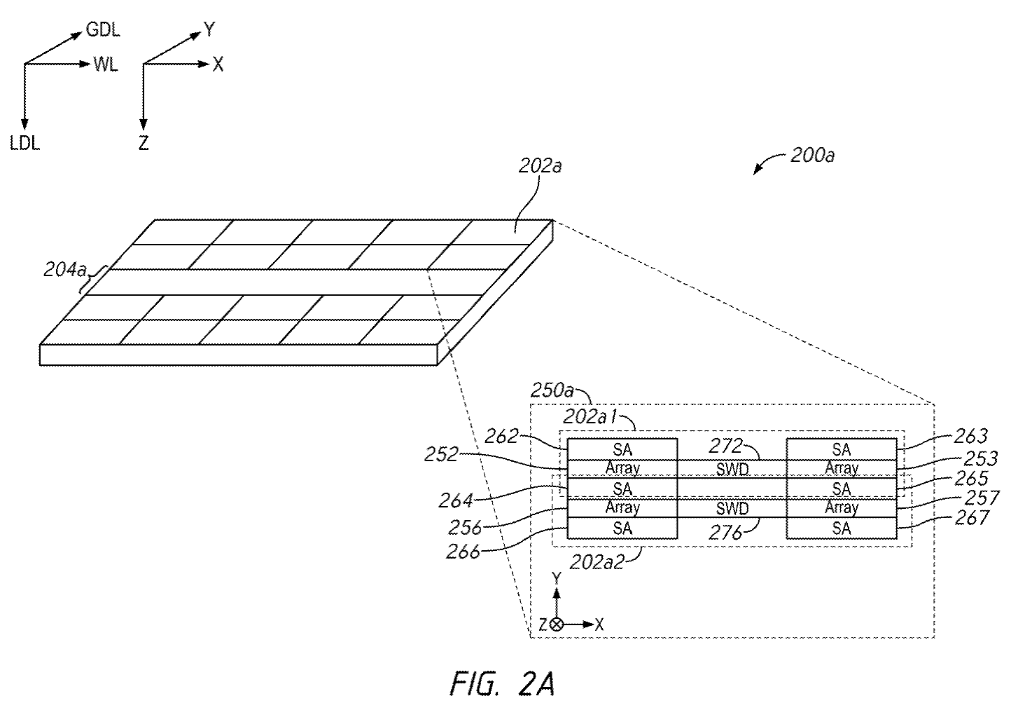

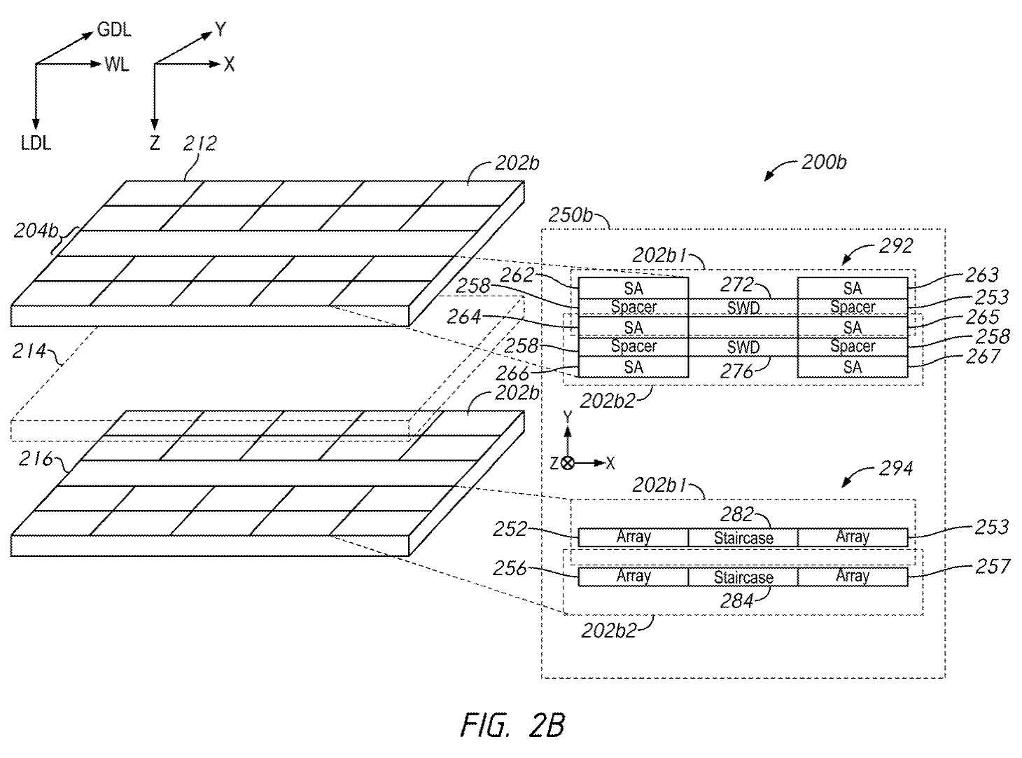

FIGS. 2A and 2B show example views of potential implementations of the memory device 100 of FIG. 1. FIG. 2A shows an example implementation where the memory device is printed on a single chip. FIG. 2B shows an example implementation where the memory device is printed on two chips which are coupled via W2W bonding.

FIG. 2A is a perspective drawing of a single die memory die with an inset showing a ‘top down’ view of two memory sections according to some example embodiments of the present disclosure. The memory die 200a may, in some embodiments, represent a layout which implements the 3D memory device 100 of FIG. 1.

The memory die 200a includes a number of memory sections 202a, each of which includes one or more sections of memory array, such as memory patches, as well as circuitry which supports the operation of those patches such as SAs (e.g., 174 of FIG. 1) and SWDs (e.g., 172 of FIG. 1). The memory sections 202a are tiled in the x-y plane of the memory die 200a. The memory die 200a also includes a peripheral region 204a, which does not have memory sections 202a tiled across it. The peripheral region 204a may include other circuits which are used in the operation of the memory such as the command circuit 114 of FIG. 1, the input and output circuits 116-122 of FIG. 1 and other components.

In the example of FIG. 2A, the peripheral region 204a extends across a width of the die 200a in an x-direction, and a portion of the surface of the die 200a in the y-direction. The peripheral region 204a is generally centered in the device along the y-axis. The device 200a has memory sections 202a positioned in a grid layout above in the +y direction and below in the -y direction the edges of the peripheral region 204a. Other arrangements of the peripheral region 204a and sections 202a may be used in other example embodiments. FIG. 2A shows a simplified view with a 2x5 grid of sections 202a on either side of the peripheral region 204a. However, more or fewer sections 202a, or different arrangements of sections 202a may generally be used in other example embodiments. For example, an implementation of a memory device may generally be expected to include many more sections 202a than the twenty sections illustrated in FIG. 2A.

The inset 250a shows a ‘top down’ view in the xy plane of two adjacent sections 202a1 and 202a2. The sections 202a1 and 202a2 represent examples of two of the sections 202a. The two sections 202a1 and 202a2 are adjacent to each other in the y direction. The inset 250a only shows two sections 202a1 and 202a2, however those sections may border other sections which are not shown in the inset 250a.

Each section 202a1 and 202a2 includes a pair of memory patches, four sense amplifier (SA) regions, and a sub word line driver (SWD) and staircase region. Section 202a1 includes memory patches 252 and 253 (also referred to as memory array patches or array patches), SA regions 262, 263, 264, and 265, and SWD and staircase region 272. Section 202a2 includes memory patches 256 and 257 (also referred to as memory array patches or array patches), SA regions 264, 265, 266, and 267, and SWD and staircase region 276.

The example layout of section 202a1 is described in detail. Since each section may be generally similar, the layout of section 202a2 is not described in detail. The section 202a1 includes a first array patch 252 and a second array patch 253. Patches 252 and 253 are generally elongated along the x axis, and are generally longer along the x axis than they are tall along the y axis. Each patch 252 and 253 is also elongated along the z-axis, which is not shown in the ‘top down’ view of FIG. 2A. The SWD and staircase region 272 is positioned between the two array patches 252 and 253 such that the SWD and staircase region 272 separates the two patches 252 and 253 along the x axis. The SWD and staircase region 272 may be elongated in the x direction and may be longer in the x direction than it is tall in the y direction. In some embodiments, the height of the SWD and staircase region 272 in the y-axis may approximately match the height of the two adjacent array patches 252 and 253.

Each memory array patch 252 and 253 is bordered by two sense amplifier regions positioned above and below array patches 252 and 253 in the y-direction. For example, the SA region 262 is above in a +y direction the array patch 252 and the SA region 264 is below in a -y direction the array patch 252. Similarly, the SA region 263 is above the array patch 253 in a +y direction and the SA region 265 is below the array patch 253 in a -y direction. The SA regions 262-265 may generally be elongated in the x direction. The SA regions 262-265 may generally have the same length in the x-axis as the array patches 252 and 253 they are adjacent to. The SA region 262 is separated from the SA region 263 by a gap in the x direction, and the SA region 264 is separated from the SA region 265 by a gap in the x-direction.

The memory array patches 252-257 represent a piece of the 3D array. For example, each memory patch 252-257 includes memory cells positioned at the intersection of word lines extending along the x axis and local digit lines extending in the z direction, which is into the plane of the page in the view of the inset 250a. The local digit lines are coupled together in columns running in the y direction by global digit lines.

The word lines in a section 202a1 or 202a2 extend continuously between the two array patches 252/253 or 256/257. For example, a word line may be continuous across the width of the array patch 252, through the staircase region 272 and across the width of the array patch 253. The word line intersects memory cells in the array patches 252 and 253, but not in the staircase region 272 when passing underneath the SWDs. For example, a word line intersects local digit lines and memory cells in the array patch 252, then passes through the staircase region 272 without intersecting memory cells or LDLs, and then intersects LDLs and memory cells again in the array patch 253. In other words, when considered along its length in the x direction, each word line has a gap where there are no coupled memory cells in the staircase region 272.

The SWD and staircase regions 272 and 276 include a number of SWDs, each of which is coupled to a respective word line which extends across both of the associated array patches 252/253 or 256/257. For example, a first SWD in the SWD region 272 is coupled to a first word line which extends across both array patches 252 and 253, a second SWD in the region 272 is coupled to a second word line which extends across both array patches 252 and 253, and so forth. The SWDs in the SWD region 272 or are arranged in a grid, which has dimensions based on the number and arrangement of word lines in the adjacent memory patches 252/253 or 256/257. For example, if there are M word lines in the y-direction and N word lines in the z direction across the two patches 252/253 or 256/257 for a total of NxM word lines in each section 202a1 or 202a2, then there will also be NxM SWDs in the SWD region 272 or 276. For example, the region 272 may have a grid of SWDs with M SWDs in the y-direction and N SWDs in the x direction. Along a given row in the x direction, each SWD couples to a different depth of word line in the z-direction using a connective element which extends along the z-direction to the associated word line.

The sense amplifier regions 262-267 each include a number of sense amplifiers, each of which is coupled to a respective global digit line in the adjacent array patches 252-257. In the implementation of FIG. 2A, the sense amplifiers in the SA regions 262-267 may generally couple to alternate global digit lines. For example, the sense amplifiers in the SA region 262 may couple to ‘even’ global digit lines in the array patch 252, while the sense amplifiers in the SA region 264 may couple to ‘odd’ global digit lines in the array patch 252.

The two sections 202a1 and 202a2 may share components. For example, the sense amplifier regions 264 and 265 include sense amplifiers which are coupled to global digit lines in both of the adjacent memory sections 202a1 and 202a2. For example, the sense amplifier region 264 is coupled to global digit lines in both array patches 252 and 256 and the sense amplifier region 265 is coupled to global digit lines in both array patches 253 and 257. The sense amplifiers in the SA region 264 may couple to odd global digit lines in both of the adjacent array patches 252 and 256. Similarly, the sense amplifiers 262 may couple to even global digit lines in the array patch 252 and a different array patch adjacent on the other side, not shown in the inset 250a. The sections 202a which are on the edge of the die 200a with no adjacent section in the y-direction may have a region of sense amplifiers which are not shared, but instead only couple to global digit lines in the one adjacent patch.

In an example implementation, each of the memory patches 252-257 may include about 1Mbit of storage or about 1,024,000 memory cells. A given section 202a1 or 202a2 has 1000 word lines arranged in a grid in the yz plane of 10 word lines in the y direction and 100 in the z direction. Each associated sense amplifier region 262-267 includes about 512 sense amplifiers coupled to half of the global digit lines which cross the array section 252, for a total of 1024 global digit lines in each memory section 252-257. The SWD and staircase regions 272 and 276 each include 1000 SWDs, arranged in a grid in the xy plane of 10 SWDs in the y direction and 100 in the x direction.

FIG. 2B is a is a perspective drawing of a stacked die memory device with an inset showing a ‘top down’ view of two memory sections according to some example embodiments of the present disclosure. The memory device 200b may, in some embodiments, represent a layout which implements the 3D memory device 100 of FIG. 1. The memory device 200b may be generally similar to the memory die 200a, except the memory device 200b is a stacked memory device where two die are bonded together to form the memory device, rather than having the memory device printed on a single die. Since the memory device 200b may be generally similar to the memory die 200a of FIG. 2A, certain details already explained with respect to FIG. 2A will not be repeated again with respect to FIG. 2B.

The memory device 200b is formed from two die, a first die 212 and a second die 216. The first die 212 is stacked on top of the second die 216 in the z-direction. The first die 212 may be a die which includes various circuits and components which operate the memory device 200b, while the second die 216 may be an array die which includes the memory cells, word lines, local digit lines and global digit lines. The second die 216 may also include components which are used to couple components together such as the staircase. The first die 212 may generally be referred to as a CMOS die and the second die 216 may generally be referred to as an array die.

The two die 212 and 216 may be bonded together. For example, wafer-to-wafer (W2W) bonding may be used. A bottom surface in the z direction of the first die 212 may have one or more connection points such as bumps. A top surface in the z direction of the second die 216 may have corresponding connection points such as bumps. When the two die are bonded, the connection points may be electrically coupled between corresponding bumps. In some embodiments, an optional bonding layer 214 between the two die may be used.

Both die 212 and 216 have memory sections 202b which are tiled across the surface of the two die. Each memory section 202b has a portion on the first die 212 and a portion on the second die 216. The portions of a given memory section across the two die are vertically stacked so they align in an x-y plane and are stacked in the z direction. Each of Die 212 and die 216 also has a peripheral region 204b which does not have memory sections 202b tiled across it. The peripheral region 204b may include other circuits which are used in the operation of the memory. The peripheral region 204b extends across a width of the die 212/216 in the x-direction and a portion of the surface of the die 212/216 in the y-direction. The peripheral region 204b is generally centered in the device along the y-axis. The position of the peripheral region 204b of the die 212 generally matches the position of the peripheral region 204b in the z direction. The peripheral region 204b of the die 212 is generally above the peripheral region 204b, or vice versa.

The inset 250b shows an example of two sections 202b1 and 202b2. The inset shows a first portion 292 which is in the first die 212 and a second portion 294 which is in the second die. The layout of the sections 202b1 and 202b2 may be generally similar to the sections 202a1 and 202a2 of FIG. 2A except that in FIG. 2B, the sections 202b1 and 202b2 are split across two dice. In particular, the sense amplifier regions 262-267 and SWD regions 272 and 276 are located in the portion 292 on the first die 212, while the array patches 252-257 and the staircase regions 282 and 284 are located in the portion 294 on the second die 216.

The portion 292 includes spacer regions 258, located on either side of the SWD regions 272 and 276 and between the SA regions 262-267. These spacer regions 258 are located above the memory array patches 252-257 in the z direction. The spacer regions 258 may be regions of the first die 212 which are generally empty of circuits in some embodiments.

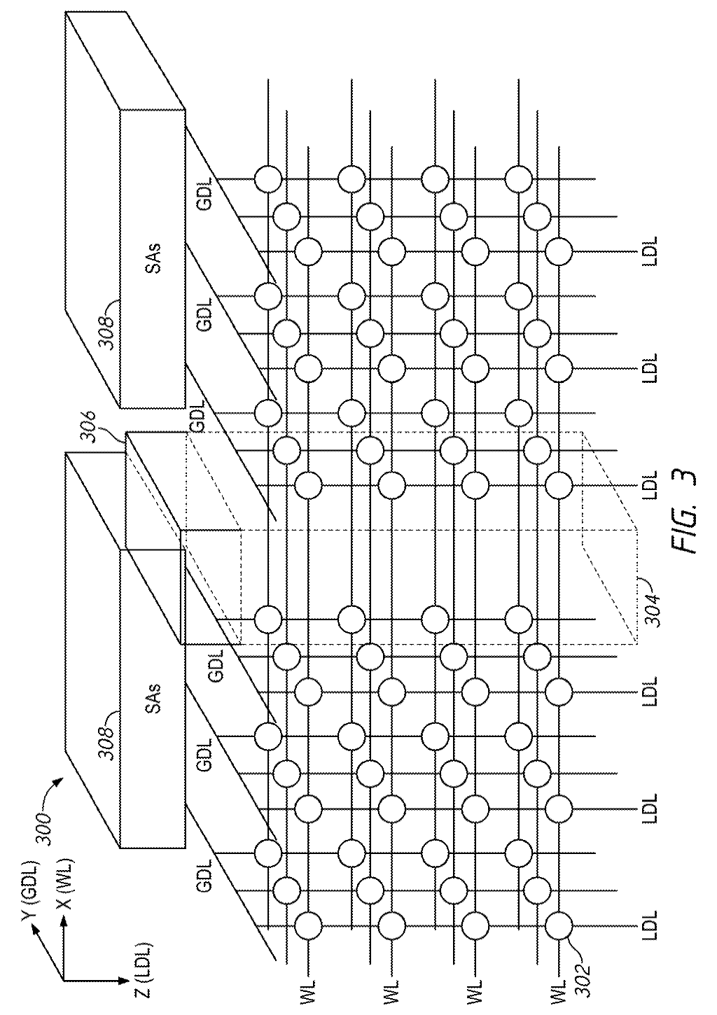

FIG. 3 is a perspective schematic diagram of a portion of a 3D memory array according to some embodiments of the present disclosure. The 3D memory array 300 represents a simplified view of an example portion of a memory array. For example, the 3D memory array 300 may represent a portion of the 3D memory array 180 of FIG. 1, and/or 252-257 of FIGS. 2A and 2B. The perspective of FIG. 3B shows an example set of memory cells 302 and their respective word lines, local digit lines and global digit lines.

The memory array 300 shows memory cells 302. Each memory cell 302 is positioned at the intersection of a word line WL and a local digit line LDL. The LDLs are coupled together by global digit lines GDL. The global digit lines are coupled to respective sense amplifiers in sense amplifier regions 308 (e.g., 174 of FIG. 1 and/or 262-267 of FIGS. 2A-2B). The word lines are each coupled to a respective SWD in a SWD region 306 (e.g., 172 of FIG. 1 and/or 272-276 of FIGS. 2A-2B). The word lines are coupled via a staircase region 304 (e.g., 182 of FIG. 1, 272-276 of FIG. 2A, and/or 282-284 of FIG. 2B) to the SWD region 306.

In some embodiments, such as the embodiment of FIG. 2A, the SA regions 308 and the SWD region 306 may be in the same die as the WL, LDL, GDL, and memory cells 302. In some embodiments, such as the embodiment of FIG. 2B, the SA regions 308 and the SWD region 306 may be in a different die than the die which includes the WL, LDL, GDL, and memory cells 302.

The staircase region 304 is a 3D region, which may be generally have the form of a rectangular prism. The staircase region 304 is positioned underneath the SWD region 306 in the z-direction. In some embodiments, the staircase region 304 may have the same x-y dimensions as the SWD region 306. The staircase region 304 is positioned between two sections of the word lines WL which intersect memory cells 302. However, the WLs may not intersect any memory cells while they pass through the staircase region 304. Vertical connection elements which extend in the z direction (not shown in FIG. 3) couple each word line to a respective SWD in the SWD region 306. A middle of the word lines WL may be positioned in the staircase region 304.

The word lines WL are arranged in a grid when considered in the yz plane. Similarly, the LDLs may be arranged in a grid when considered in the xy plane. The GDLs are generally arranged in a plane side-by-side with each other.

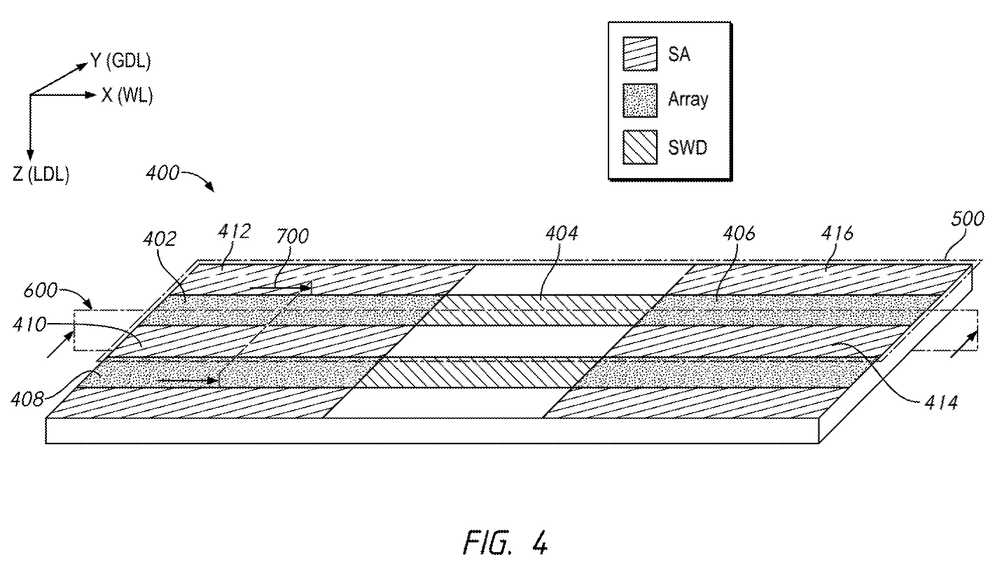

FIG. 4 is a perspective view of a portion of a 3D memory device according to some embodiments of the present disclosure. The 3D memory device 400 may represent a portion of a memory device such as 100 of FIG. 1, 200a of FIG. 2A and/or 200b of FIG. 2B. The memory device 400 may include a memory array similar to the layout of the memory array 300 of FIG. 3 in some embodiments. The memory device 400 shows two adjacent sections of a memory array, similar to the view of the insets 250a and 250b of FIGS. 2A-2B. However, FIG. 4 shows a perspective view rather than a ‘top down’ view of the xy plane.

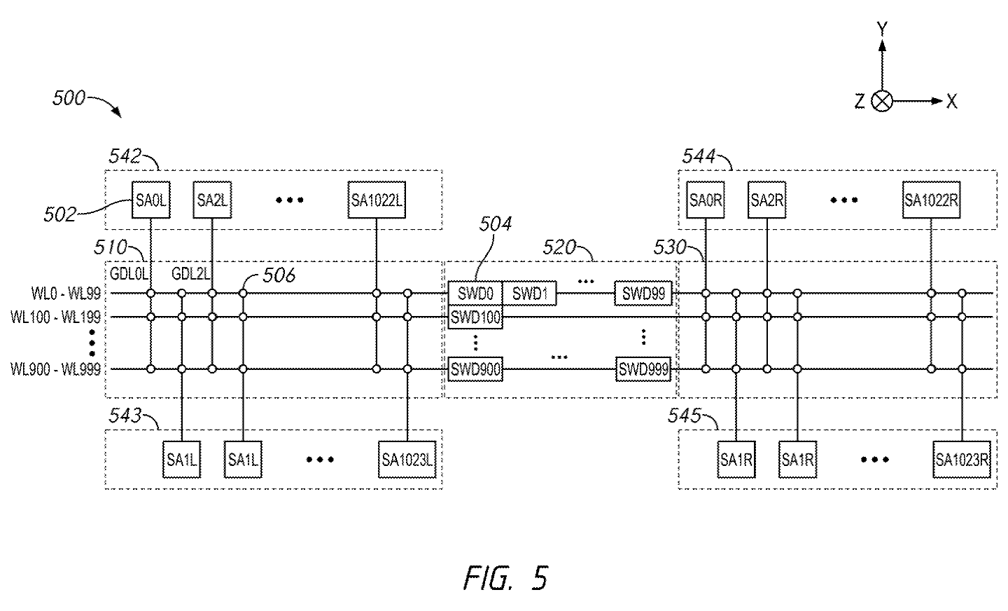

FIG. 4 shows planes 500, 600, and 700 which represent the views of FIGS. 5, 6, and 7 respectively. The plane 500 is a slice along an xy plane of the memory device 400 which intersects a first patch 402 (e.g., 252 of FIGS. 2A-2B), a SWD and staircase region 404 (e.g., 272 and 282 of FIGS. 2A-2B), a second memory patch 406 (e.g., 253 of FIGS. 2A-2B), and the sense amplifier regions 410-416 (e.g., 262-267 of FIGS. 2A-2B). The plane 600 is a slice along an xz plane of the memory which intersects a first memory patch 402, a SWD and staircase region 404 and a second memory patch 406. The plane 700 is a slice along a yz plane which intersects the first memory patch 402, a sense amplifier region 410 (e.g., 264 of FIGS. 2A-2B) and a third memory patch 408 (e.g., 256 of FIGS. 2A-2B). The first memory patch 402 and the second memory patch 406 are on opposites sides of the SWD and staircase region 404 and are part of a same memory section (e.g., 202a1 of FIG. 2A and/or 202b1 of FIG. 2B). The first memory patch 402 and the third memory patch 408 are on opposite sides of the sense amplifier region 410 and are part of different memory sections.

FIGS. 5-7 show different cross-sectional views of the 3D memory device 400 of FIG. 4. Each of FIGS. 5-7 is illustrated with respect to an example embodiment where each memory patch such as 402, 406 or 408 includes 1 Mbit of memory cells. Specifically, they are shown to include a grid of 10 word lines in the y direction and 100 word lines in the z direction, a grid of 10 LDLs in the y direction and 1024 LDLs in the x direction, and 1024 global digit lines side-by-side. This arrangement is shown as an illustrative example only. Other numbers and/or arrangements of word lines, global digit lines, local digit lines, memory cells, sense amplifiers, and so forth may be used in other example embodiments.

FIG. 5 is a cross sectional view of a 3D memory device according to some embodiments of the present disclosure. The cross section 500 shows the plane 500 of FIG. 4. The cross section 500 represents a view along an example xy plane, showing a top layer of word lines extending horizontally in the x direction, global digit lines extending in the y direction, and local digit lines 506 extending into the plane of the page in the z direction. The view of FIG. 5 shows a slice of the ‘top’ word lines in a stack of word lines, with additional word line extending down in the z direction. The cross sectional view of FIG. 5 shows a view of components which are not contained within a single plane. For example, the SWDs 504 and sense amplifiers 502 may generally be located in a plane which is above the plane of the word line in the z direction. However, they are shown in FIG. 5 to help aid in understanding the connections between and placement of various components.

The cross section 500 shows a first memory patch 510 (e.g., 252 of FIGS. 2A-2B and/or 402 of FIG. 4), a SWD and staircase region 520 (e.g., 272 of FIGS. 2A-2B and/or 404 of FIG. 4), and a second memory patch (e.g., 253 of FIGS. 2A-2B and/or 406 of FIG. 4). Also shown are sense amplifier regions 542-545 (e.g., 262-265 of FIGS. 2A-2B and/or 410-416 of FIG. 4). The view of FIG. 5 may represent a single memory section (e.g., 202a of FIG. 2A and/or 202b of FIG. 2B). The first memory patch 510 and the second memory patch 520 are located on opposite sides of the SWD and staircase region 530 in the x direction. The sense amplifier regions 542 and 543 are located on opposite sides of the first patch 510 in the y direction and the sense amplifier regions 544 and 545 are located on opposite sides of the second patch 530 in the y direction.

The cross section 500 includes word lines WL0 to WL999. The word lines are arranged in 10 stacks of 100 word lines each. So the top row of word lines includes the visible word line (WL0) as well as 99 more word lines extending in the z direction into the plane from the point of view of the drawing. The tops of local digit lines 506 are shown where they intersect a global digit lines GDL. The LDLs 506 are arranged in a grid layout in an xy plane, with a row of the grid including 1024 LDLs along the x direction and a column of the grid including of 10 LDLs along the y direction. The GDL extends in the y direction to a sense amplifier 502 in a sense amplifier region 542-545. The word lines WL extend from the first patch 510 to the second patch 530 under the SWD and staircase region 520.

The SWD and staircase region 520 includes a number of SWDs 504. There is a SWD for each word line. In this example there are 1000 SWD, arranged in a grid of 10x100 SWDs in the yz plane. The SWDs 504 are arranged in 10 rows, with each row over a stack of WLs. Since the stacks of WLs are arranged with 100 WLs in each stack, each row of SWDs has 100 SWDs. Each SWD along a row has a conductive element running in the z direction down to the WL it is coupled to. The SWDs along a ‘row’ of the grid of SWDs are coupled to conductive elements of different lengths, since they are coupled to different depths (in the z direction) of word line. When activated by a row activation command, the SWD associated with the row address activates the associated word line.

The global digit lines in each patch 510 and 530 are alternately coupled to one of the two adjacent sense amplifier regions. For example, the regions 542 and 544 may be even sense amplifier regions with SAs 502 coupled to even ones of the GDLs, while the region 543 and 545 may be odd sense amplifier regions with SAs 502 coupled to odd ones of the GDLs. In the example implementation of FIG. 5, each of the regions 542-545 includes 512 sense amplifiers 502, each coupled to a respective GDL. The global digit lines are labelled as left GDLs GDL0L to GDL1023L and right GDLs GDL0R to GDL1023R. Similarly, the sense amplifiers are labelled SA0L to SA1023L and SA0R to SA1023R. Except for edge sections, the sense amplifiers 502 may also generally be coupled to another GDL extending into an adjacent memory patch, not shown in FIG. 5.

When a row activation command is received along with a row address, the SWD 504 associated with that address activates the associated word line. When activated, the memory cells along that word line are coupled to the intersecting LDL 506, and change a voltage of the LDL and the GDL that LDL is coupled to based on the stored charge. The SA coupled to that GDL senses this change and amplifies it during a read operation, or drives a new value onto the GDL in a write operation.

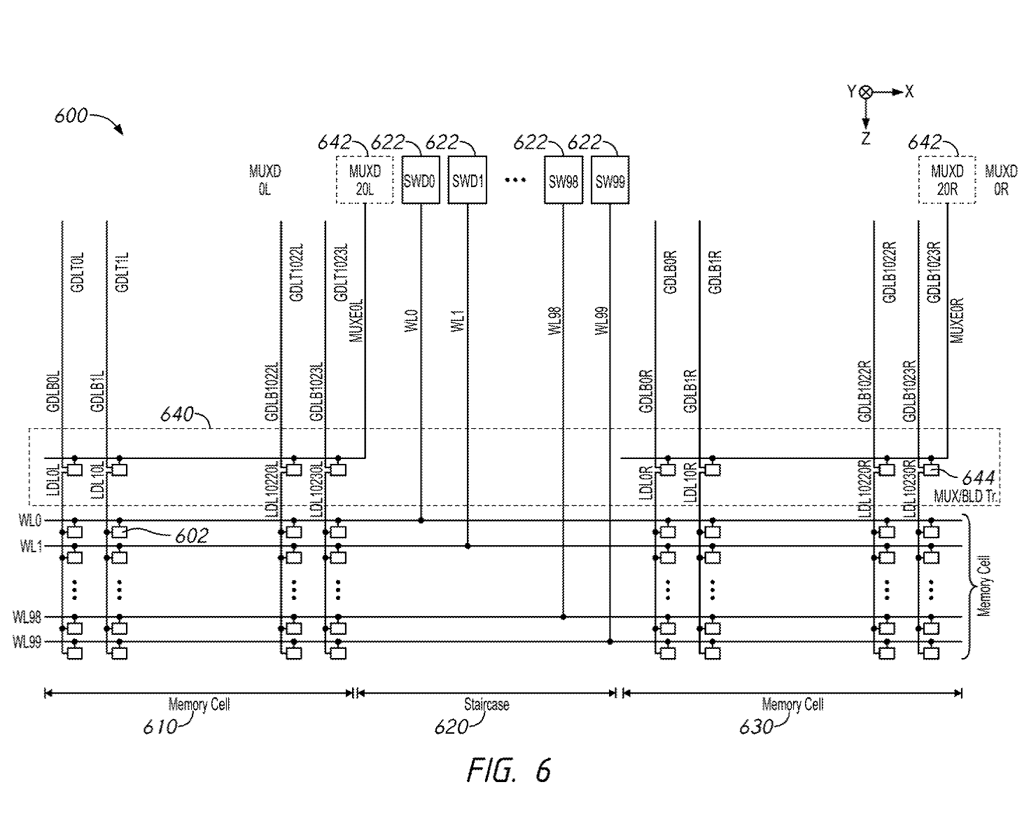

FIG. 6 is a cross sectional view of a 3D memory device according to some embodiments of the present disclosure. The cross section 600 shows the plane 600 of FIG. 4. The cross section 600 represents a view along an example xz plane, showing word lines running horizontally along the x direction, local digit lines running vertically along the z direction, and global digit lines running into and out of the plane of the page along the y direction. A portion of the global digit lines is also shown running vertically in the z direction to show the global digit lines coupling to their respective sense amplifiers. These vertical elements of the GDLs may alternate between being ‘in front’ of the plane of the cross section 600 or ‘behind’ the plane of the cross section 600 in the y direction. These may run to alternate sense amplifier regions such as 262/264 of FIGS. 2A-2B, 412/410 of FIG. 4, and/or 542/543 of FIG. 5.

The cross section 600 shows a first memory patch 610 (e.g., 252 of FIGS. 2A-2B, 402 of FIG. 4, and/or 510 of FIG. 5), a staircase region 620 (e.g., 272 of FIGS. 2A-2B, 404 of FIG. 4, and/or 520 of FIG. 5), and a second memory patch 630 (e.g., 253 of FIGS. 2A-2B, 406 of FIG. 4, and/or 530 of FIG. 5). The cross section 600 also shows a row a SWDs 622 associated with the WLs.

Each word line is coupled to a respective SWD 622. For example the cross section 600 shows SWD0 to SWD99, which are associated with WL0 to WL99 respectively. The SWDs 622 are located above in the z direction a staircase region 620 which is between the two patches 610 and 630 in the x direction. Each SWD 622 is coupled to a vertical conductive element which extends in the z direction to the associated word line. Along a row of SWDs 622 like the one shown in FIG. 6, each of these vertical conductive elements 624 may be a different length, since the WLs are at different depths in the z direction. In the example layout of FIG. 6, the shortest vertical conductive element 624, coupled to the ‘top’ word line WL0, is on the far left, while the longest vertical conductive element 624, coupled to the ‘bottom’ word line WL99, is on the far right. Other arrangements may be used in other example embodiments.

The cross section 600 shows a ‘stack’ of word lines. In this case the word lines WL0 to WL99. A number of LDLs extend vertically in the z direction and memory cells 602 are coupled at the intersection of the LDLs and the WLs. In the example implementation, there are 10,240 LDLs per patch from LDL0 to LDL10239. Each LDL seen in the cross section 600 represents a ‘top’ of a stack of 10 LDLs which extend in the y direction. Thus the leftmost LDL in the patch 610 is LDL0L, the next LDL is LDL10L, the next is LDL20L and so forth up to LDL10230L. Similarly, the LDLs in the patch 630 are LDL0R up to LDL10230R.

Responsive to a row activation command and a row address, the SWD specified by the row address activates the coupled word line along the respective vertical conductive element 624. This couples the memory cells 602 in the two patches 610 and 630 to be coupled to the LDLs which intersect that word line. Those LDLs are in turn coupled to respective GDLs, which run to sense amplifier regions.

The view of FIG. 6 includes optional digit line multiplexers 622 (e.g., 184 of FIG. 1) in a digit line multiplexer region 640, and example multiplexer drivers 642. In some embodiments, these components may be omitted, and the LDLs may couple directly to the GDLs. In example embodiments where multiplexers are used, the multiplexers 644 selectively couple a set of LDLs to the respective GDLs. In the xz slice shown in FIG. 6, the multiplexers 644 of the left patch 610 are coupled to a multiplexer driver 642 and the multiplexers 644 of the right patch 630 are coupled to a multiplexer driver 642. Responsive to a signal from a global row decoder (e.g., 166 of FIG. 1), the multiplexer drivers 642 activate the multiplexers 644 to couple the LDLs along the cross section 600 to their respective GDLs. The other LDLs, which are stacked in the Y direction and not visible in FIG. 6, are coupled to multiplexers which are coupled to different multiplexer drivers, and thus are not coupled to the GDLs. This may help reduce the capacitance of the GDL since each GDL is only coupled to one LDL at a time.

In some embodiments, the SWDs 622 and, if used, multiplexer drivers 642 may be located in a CMOS die (e.g., 212 of FIG. 2B) while the memory cells, LDLs, WLs, and, if used multiplexer region 640 are located in an array die (e.g., 216 of FIG. 2B). The vertical conductive elements 624, as well as the vertical portions of the GDLs may extend from the array die to the CMOS die and may include contacts between the two dice not shown in FIG. 6.

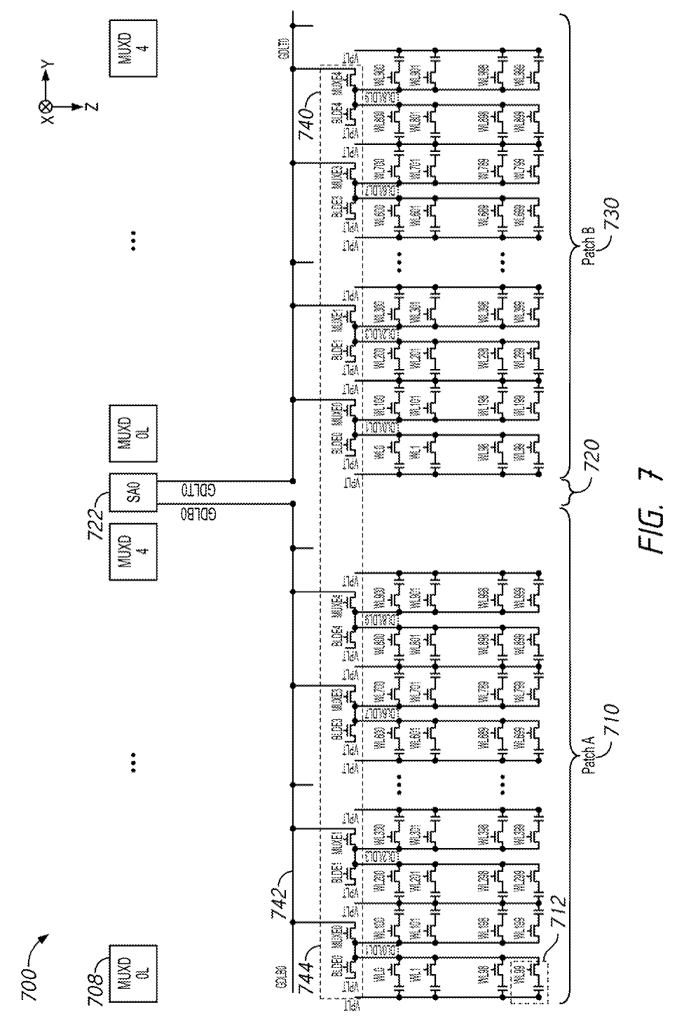

FIG. 7 is a cross sectional view of a 3D memory device according to some embodiments of the present disclosure. The cross section 700 shows the plane 700 of FIG. 7. The cross section 700 represents a view along an example yz plane, showing two global digit lines running horizontally in the y direction, local digit lines running vertically in the z direction, and word lines running through the plane of the page in the x direction. The cross section 700 shows a first memory patch 710 (e.g., 252 of FIGS. 2A-2B, 402 of FIG. 4, 510 of FIG. 5, and/or 610 of FIG. 6), a sense amplifier region 720 (e.g., 264 of FIGS. 2A-2B, 410 of FIG. 4, and/or 543 of FIG. 5), and a second memory patch 730 (e.g., 256 of FIGS. 2A-2B, and/or 408 of FIG. 4).

The cross section 700 intersects 1000 word lines in each memory patch 710 and 730. The word lines are organized in a grid in the yz plane with ten columns in the y direction that have 100 word lines each in the z direction. Accordingly, the cross section shows 1000 memory cells 712 organized in a grid of 10 memory cells in the x direction and 100 memory cells in the z direction in each of the two patches 710 and 730. Each column of memory cells 712 is coupled to a local digit line, here labelled LDL0 to LDL9. In the embodiment of FIG. 7, the LDLs are paired and each pair LDLs is coupled in common to a multiplexer transistor 742 and a bleed transistor 744 as described in more detail herein. In some embodiments, each LDL may couple separately through a multiplexer to the GDL, rather than being paired. In some embodiments, where multiplexers are not used, the LDLs may couple directly to the GDL.

Each memory cell 712 includes a capacitive element and a transistor. The gate of the transistor is coupled to the word line. One side of the capacitive element is coupled to a plate voltage VPLT, and the other side is coupled through the transistor to the LDL. When the word line is activated, the SWD (e.g., 504 of FIG. 5 and/or 622 of FIG. 6) drives a voltage along the word line which activates the transistor, coupling the capacitive element to the LDL.

The sense amplifier region 720 includes an example sense amplifier 722. The sense amplifier 722 is labelled as SA0 because it is coupled to GDL0 in two adjacent patches 710 and 730. To distinguish them, those GDLs are labelled as GDLB0 in the first patch 710 and GDLT0 in the second patch 730. During an example operation, one of the two GDLs is used to carry information, and the other is used as a reference. For example, if a word line is activated in the first patch 710, then information is carried along GDLB0 and GDLT0 is used as a reference. During a read operation, the sense amplifier 722 senses a difference between the GDL with information and the reference and then amplifies that difference.

FIG. 7 shows an optional multiplexer region 740 along with optional multiplexer drivers 708 which operates the multiplexer transistors 742 and bleed transistors 744 of the multiplexer region 740. Each pair of LDLs is coupled to the GDL through a multiplexer transistor 742. The gate of the multiplexer transistor 742 is coupled to a multiplexer control signal MUXE which is coupled to respective multiplexer drivers 708 along a signal line which runs in the x direction. Also shown in FIG. 7 is an optional bleed transistor 744 which couples each pair of LDL to the plate voltage VPLT. The bleed transistors 744 have gates coupled to bleed control signals BLDE which are coupled to respective multiplexer drivers 708 along signal lines which run in the x direction. The multiplexer drivers 708 are controlled by global row decoders (e.g., 166 of FIG. 1).

During an example operation, if a row address is received associated with the first patch 710, then the multiplexer driver 708 which controls the LDL which intersects the WL activates the multiplexer transistor 742 by providing MUXE, and each of the other multiplexer drivers 708 provide BLDE to their respective bleed transistor 744 to couple those LDLs to VPLT and prevent them from floating. For example, if the row address indicates WL 101, which intersects LDL1, then MUXD0 provides MUXE0, which couples both LDL0 and LDL1 to GDLB0. The multiplexer drivers MUX1 to MUX4 provide BLDE1 to BLDE4 respectively, which couple the other LDLs LDL2 to LDL9 to VPLT through the respective bleed transistors 744.

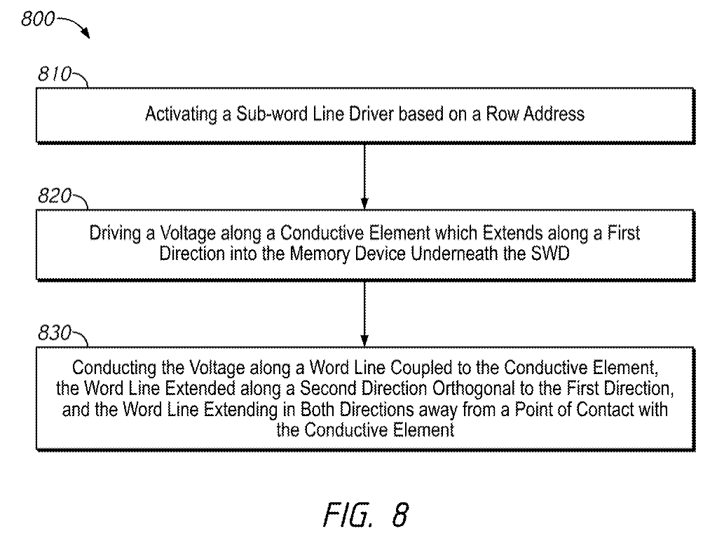

FIG. 8 is a flow chart of a method of activating word lines in a 3D memory device according to some embodiments of the present disclosure. The method 800 may, in some embodiments, be performed by any of the apparatuses and/or systems described herein. For example, the method 800 may be performed by the memory device 100 of FIG. 1, the memory sections 200a of FIG. 2A, 200b of FIG. 2B, the memory array 300 of FIG. 3, the memory device 400 of FIG. 4, the cross-section 500 of FIG. 5, 600 of FIG. 6, and/or 700 of FIG. 7.

The method 800 generally begins with box 810 which describes activating a sub-word line driver (e.g., 172 of FIG. 1, 272-276 of FIGS. 2A-2B, 306 of FIG. 3, 404 of FIG. 4, 504 of FIG. 5, and/or 622 of FIG. 6) based on a row address. For example the row address may be received along with a row activation command. The row address may specify one of the sub-word line drivers.

Box 810 is generally followed by box 820, which describes driving a voltage along a conductive element (e.g., 624 of FIG. 6) which extends along a first direction (e.g., along a z axis) into the memory device under the SWD. The conductive elements may be positioned in a staircase region (e.g., 182 of FIG. 1, 272-276 of FIG. 2A, 282-284 of FIG. 2B, 304 of FIG. 3, 404 of FIG. 4, and/or 620 of FIG. 6).

Box 820 is generally followed by box 830 which describes conducting the voltage along a word line coupled to the conductive element, the word line extended along a second direction (e.g., along an x axis) orthogonal to the first direction, with the word line extending in both direction away from a point of contact with the conductive element. The method 800 may include coupling memory cells which intersect the word line to respective local digit lines responsive to the conducted voltage.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a first 3D memory patch including a first plurality of memory cells arranged in a 3D array;
a second 3D memory patch including a second plurality of memory cells arranged in a 3D array;
a staircase region positioned between the first memory patch and the second memory patch;
a word line extending in a first direction through the first memory patch, through the staircase region, and through the second memory patch wherein the word line intersects a row of the first plurality of memory cells and a row of the second plurality of memory cells;
a sub-word line driver positioned above the staircase region, wherein the sub-word line driver is coupled to the word line by a conductive element which extends in a second direction which is generally orthogonal to the first direction.

2. The apparatus of claim 1, wherein the word line intersects memory cells in the first memory patch and the second memory patch, but not in the staircase region.

3. The apparatus of claim 1, further comprising a local digit line in the first memory patch or the second memory patch, where the local digit line extends along the second direction and intersects one of the row of the first plurality of memory cells or the row of the second plurality of memory cells coupled to the word line.

4. The apparatus of claim 2, further comprising: a sense amplifier; and
a global digit line extending in a third direction which is generally orthogonal to both the first direction and the second direction, wherein the global digit line couples the local digit line to the sense amplifier.

5. The apparatus of claim 1, further comprising:
a second word line extending in the first direction through the first memory patch, through the staircase region, and through the second memory patch, wherein the second word line is positioned below the first word line in the second direction, and wherein the second word line intersects a second row of the first plurality of memory cells and a second row of the second plurality of memory cells; and
a second sub-word line driver positioned above the staircase region, wherein the second sub-word line driver is coupled to the second word line by a second conductive element which extends in the second direction.

6. The apparatus of claim 5, wherein the conductive element and the second conductive element are different lengths.

7. The apparatus of claim 5, wherein the sub-word line driver and the second sub-word line driver are positioned next to each other along the first direction.

8. The apparatus of claim 5, further comprising:
a third word line extending in the first direction through the first memory patch, through the staircase region, and through the second memory patch, wherein the third word line is positioned at a same depth as the first word line in the second direction, but adjacent to the first word line in a third direction which is orthogonal to the first direction and the second direction, and wherein the third word line intersects a third row of the first plurality of memory cells and a third row of the second plurality of memory cells; and
a third sub-word line driver positioned above the staircase region, wherein the third sub-word line driver is coupled to the third word line by a third conductive element which extends in the second direction.

9. The apparatus of claim 1, wherein a middle of the word line is within the staircase region.

10. An apparatus comprising:
a plurality of word lines each extending along a first direction, the plurality of word lines arranged in a grid with columns extending along a second direction which is orthogonal to the first direction and rows extending along a third direction which is orthogonal to both the first direction and the second direction;
a first plurality of local digit lines extending along the second direction in a first memory region;
a second plurality of local digit lines extending along the second direction in a second memory region wherein the first and the second plurality of local digit lines are arranged in respective grids having columns which extend in the third direction and rows which extend in the first direction;
a first plurality of memory cells disposed at the intersections of the first plurality of local digit lines and the plurality of word lines;
a second plurality of memory cells disposed at the intersections of the second plurality of local digit lines and the plurality of word lines;
a plurality of sub-word line drivers (SWDs) positioned between the first memory region and the second memory region, each of the SWDs coupled to a respective one of the plurality of word lines by a respective one of a plurality of conductive elements which extends in the second direction.

11. The apparatus of claim 10, wherein the plurality of SWDs are arranged in a grid with rows extending in the first direction and columns extending in the third direction.

12. The apparatus of claim 10, wherein a first SWD of the plurality of SWDs is coupled to a first conductive element of the plurality of conductive elements, and wherein the first conductive element is coupled to a first word line of the plurality of word lines,
wherein a second SWD of the plurality of SWDs is coupled to a second conductive element of the plurality of conductive elements, and wherein the second conductive element is coupled to a second word line of the plurality of word lines, and
wherein the first conductive element and the second conductive element extend different lengths in the second direction.

13. The apparatus of claim 12, wherein the first SWD and the second SWD are adjacent to each other in the first direction.

14. The apparatus of claim 10, further comprising:
a first plurality of global digit lines extending in the third direction;
a first plurality of multiplexers configured to selectively couple selected ones of the first plurality of local digit lines to the first plurality of global digit lines;
a second plurality of global digit lines extending in the third direction; and
a second plurality of multiplexers configured to selectively couple selected ones of the plurality of the second plurality of local digit lines to the second plurality of global digit lines.

15. An apparatus comprising:
a first memory region including a first plurality of memory cells arranged in a first 3D array extending in a first direction, a second direction, and a third direction;
a second memory region including a second plurality of memory cells arranged in a second 3D array extending in the first direction, the second direction, and the third direction;
a staircase region disposed between the first memory region and the second memory region;
a plurality of word lines each extending along the first direction and extending through the first memory region, the staircase region, and the second memory region, wherein each of the plurality of word lines intersects at least one of the first plurality of memory cells and at least one of the second plurality of memory cells;
a plurality of sub-word line drivers positioned above the staircase region in the second direction.

16. The apparatus of claim 15, wherein the staircase region includes a plurality of conductive elements extending in the second direction, wherein the plurality of conductive elements couple respective ones of the plurality of word lines to respective ones of the plurality of sub-word line drivers.

17. The apparatus of claim 15, wherein the plurality of sub-word line drivers are arranged in a grid with rows extending in the first direction and columns extending in the third direction.

18. The apparatus of claim 15, further comprising:
a first plurality of local digit lines (LDLs) extending in the second direction, the first plurality of LDLs extending through the first memory region;
a first plurality of global digit lines (GDLs) extending in the third direction, the first plurality of GDLs extending through the first memory region, wherein each of the first plurality of GDLs is coupled to respective ones of the first pluralities of LDLs;
a second plurality of LDLS extending in the second direction, the second plurality of LDLs extending through the second memory region; and
a second plurality of GDLs extending in the third direction, the second plurality of GDLs extending through the second memory region, wherein each of the second plurality of GDLs is coupled to respective ones of the first pluralities of LDLs.

19. The apparatus of claim 18, further comprising:
a first plurality of multiplexers configured to selectively couple selected ones of the first plurality of LDLs to the first plurality of GDLs; and
a second plurality of multiplexers configured to selectively couple selected ones of the second plurality of LDLs to the second plurality of GDLs.

20. The apparatus of claim 15, further comprising a global row decoder configured to select one of the plurality of sub-word line drivers based on a row address, wherein the selected one of the plurality of sub-word line drivers activates an associated one of the of the plurality of word lines.
